(19) United States
(12) Patent Application Publication
(10) Pub. No.: US 2020/0373114 A1
(43) Pub. Date: Nov. 26, 2020

(54) Klystron Driver

(71) Applicant: Eagle Harbor Technologies, Inc., Seattle, WA (US)

(72) Inventors: James Prager, Seattle, WA (US); Timothy Ziemba, Bainbridge Island, WA (US); Kenneth Miller, Seattle, WA (US); John Carscadden, Seattle, WA (US); Alex Henson, Seattle, WA (US); Steven Wilson, Seattle, WA (US)

(21) Appl. No.: 16/882,451

(22) Filed: May 23, 2020

Related U.S. Application Data
(60) Provisional application No. 62/852,860, filed on May 24, 2019.

(51) Int. Cl. H01J 25/10; H01J 23/24; H01J 25/38; H02M 3/158; H03K 3/57

(52) U.S. Cl. CPC H01J 25/10; H01J 23/24; H03K 3/57; H02M 3/1588; H01J 25/38

(57) ABSTRACT

Some embodiments include a resonant converter klystron driver. A resonant converter klystron driver, for example, may include an input power supply; a full-bridge circuit coupled with the input power supply; a resonant circuit coupled with the full-bridge; a step-up transformer coupled with the resonant circuit; a rectifier coupled with a step-up transformer; a filter stage coupled with the rectifier; and an output coupled with the filter stage. In some embodiments, the output could be coupled with a klystron.

### GOVERNMENT RIGHTS

This invention was made with government support under Award Number DE-SC0018687 by the Department of Energy. The government has certain rights in the invention.

### BACKGROUND

A current challenge facing the fusion science community is the ability to generate steady-state current drive in an efficient, robust manner. Some solutions require a next generation high voltage power supply (HVPS) to drive klystrons for these current drive experiments. Some existing HVPS can be the size of two shipping containers and can power eight klystrons in parallel. In this example, in the event of a fault, all eight klystrons must be shut down to prevent damage.

### SUMMARY

Some embodiments include a resonant converter klystron driver that outputs of about 50 kV with about 1.1% ripple. In some embodiments, the resonant converter klystron driver outputs an output current of 6 A. In some embodiments, the resonant converter klystron driver inputs an input voltage of 13.8 kVAC, 480 VAC, or 600 V.

Some embodiments include a resonant converter klystron driver including an input power supply; a full-bridge coupled with the input power supply ;a resonant circuit coupled with the full-bridge; a step-up transformer coupled with the resonant circuit; a rectifier coupled with a step-up transformer; a filter stage coupled with the rectifier; and an output coupled with the filter stage and configured to be coupled with a klystron. In some embodiments, the filter stage comprises a capacitor and stray inductance. In some embodiments, the output outputs 50 kV with about 1.1% ripple.

Some embodiments include a resonant converter klystron driver comprising: an input power supply; a full- or half-bridge coupled with the input power supply; a resonant circuit coupled with the full-bridge; a step-up transformer coupled with the resonant circuit; a rectifier coupled with a step-up transformer; a filter stage coupled with the rectifier; and an output coupled with the filter stage and configured to be coupled with a klystron. In some embodiments, the filter stage comprises a capacitor and stray inductance. In some embodiments, the output outputs 50 kV with about 1.1% ripple.

Some embodiments include a resonant converter klystron driver comprising an input power supply; a plurality of circuits arranged in parallel; and an output coupled with the filter stage and configured to be coupled with a klystron. Each circuit may include a half-bridge or full-bridge coupled with the input power supply; a resonant circuit coupled with the half-bridge or full-bridge; a step-up transformer coupled with the resonant circuit; a rectifier coupled with a step-up transformer; and a filter stage coupled with the rectifier. In some embodiments, the filter stage comprises a capacitor and stray inductance. In some embodiments, the output outputs 50 kV with about 1.1% ripple.

These illustrative embodiments are mentioned not to limit or define the disclosure, but to provide examples to aid understanding thereof. Additional embodiments are discussed in the Detailed Description, and further description is provided there. Advantages offered by one or more of the various embodiments may be further understood by examining this specification or by practicing one or more embodiments presented.

### BRIEF DESCRIPTION OF THE FIGURES

These and other features, aspects, and advantages of the present disclosure are better understood when the following Detailed Description is read with reference to the accompanying drawings.

FIG. 1 is a circuit diagram of a full-bridge resonant converter klystron driver according to some embodiments.

FIG. 2A shows output voltage from a single resonant converter klystron driver. FIG.

2B shows output voltage from a four resonant converter klystron driver.

FIG. 3 are waveforms from a full-bridge resonant converter klystron driver coupled with a resistive load.

FIG. 4A, 4B, and 4C show results from a single resonant converter klystron driver with transformer and rectifier driving a resistive load according to some embodiments.

FIG. 5 are waveforms of the voltage output of A two resonant converter klystron driver according to some embodiments.

FIG. 6 are waveforms of the voltage output of the two resonant converter klystron driver according to some embodiments.

FIG. 7 a circuit diagram of four full-bridge resonant converters arranged in parallel driving a klystron load according to some embodiments.

FIG. 8 is a waveform showing the output voltage of each of the full-bridge resonant converters in FIG. 7.

### DETAILED DESCRIPTION

Some embodiments include a resonant converter klystron driver that produces an output voltage of about 50 kV with less than about 1.1% ripple, an output current of at least about 3 amps (or more) per converter, and/or a power of at least about 150 kW (or more) per converter for shot lengths more than about 500 μs, 800 μs, 1 ms, 100 ms, 500 ms, 1 s, 10 s, etc.

Some embodiments may include two or more resonant converter klystron drivers couple together with one HVPS per resonant converter klystron driver. This may, for example, simplify operation and may allow experiments to continue in the event of a klystron fault as the remaining klystrons can continue to operate.

In some embodiments, a resonant converter klystron driver may include a solid-state resonant converter. A solid-state resonant converter, for example, can include a full-bridge (or half bridge), a resonant circuit, a step-up transformer, a rectifier, and/or a filter. In some embodiments, a solid-state resonant converter can provide a high-voltage, low-ripple, square pulse. A solid-state resonant converter, for example, may be efficient; driving the resonant circuit may allow for switching at nearly zero current, significantly reducing losses. In some embodiments, the solid-state converter can be operated at a high switching frequency, which can reduce both the size of the transformer and the output ripple. This can, for example, allow for smaller filtering elements to be used, storing less energy, or reducing the risk of damage to the load during a fault. In some embodiments, a solid-state system may also provide fast response times or a high degree of control.

In some embodiments, a solid-state resonant converter klystron driver can produce output voltage of at least about 25, 50, or 100 kV, with less than about ±1% ripple, and/or less than about 1 J, 5 J, 10 J, etc. of energy stored in the filter elements. In some embodiments, a solid-state resonant converter can include four resonant converters in parallel and out of phase to drive a single klystron.

In some embodiments, two resonant converters can be combined together to increase the current. For example, a single resonant converter can produce 50 kV and 3 A output. Two resonant converters can be combined together to produce 50 kV and 6 A output. In some embodiments, the two converters can be operated out of phase or produce a ripple of ±1%, which is lower as compared to ±5% for a single converter, while also reducing the stored energy. Adding two more converters in parallel may also reduce the filter size and ripple even further.

In some embodiments, a resonant converter klystron driver can produce an output voltage of about 25, 50, or 100 kV with a ripple less than or equal to about ±1%.

In some embodiments, a resonant converter klystron driver can produce an output current of about 12 A per klystron.

In some embodiments, a resonant converter klystron driver can produce an output pulse with a voltage or current with a rise time less than about 600 μs.

In some embodiments, a resonant converter klystron driver can produce an output pulse with a voltage or current fall time less than about 30 μs.

In some embodiments, a resonant converter klystron driver can produce an output pulse with a pulse length of about 10 s every 10 min.

In In some embodiments, a resonant converter klystron driver filter may store less than about 10 J (or less) of energy, which would be delivered to the klystron in the event of a fault.

In some embodiments, a resonant converter klystron driver can include a full-bridge circuit (or half-bridge circuit) produces a waveform that drives a resonant circuit at resonance, a step-up transformer, for example, to obtain the desired voltage, and a full-wave rectifier and/or filter to provide a high-voltage, low-ripple, square pulse. In some embodiments, a possible advantage of a resonant converter klystron driver is its efficiency; driving the resonant circuit at resonance allows for switching at nearly zero current, which may significantly reduce losses. In some embodiments, a resonant converter klystron driver may allow for an increased switching frequency, which in turn may reduce both the size of the transformer or the output ripple. In some embodiments, a resonant converter klystron driver may allow for smaller filtering elements to be used, which can store less energy and reduces damage to the load during a fault.

In some embodiments, a possible advantage of a resonant converter klystron driver is that it can provide fast response times.

In some embodiments, a possible advantage of a resonant converter klystron driver is that it can provide a high degree of control.

In some embodiments, a resonant converter klystron driver can include a full-bridge that can be operated at about 50-500 kHz (e.g., 125 kHz). This may, for example, allow for a very compact design. In some embodiments, the output voltage of the system could be modulated using the duty cycle of the resonant converter klystron driver. In some embodiments, the output may have a duty cycle of about 10% to 100%, which may result in a output of 5 kV to 50 kV.

In some embodiments, a resonant converter klystron driver can operate with any input whether DC or AC with voltages from about 1 kV to about 25 kV such as, for example, 12.5, 13.8 kVAC or 480 VAC. Yet, any input voltage can be used. In some embodiments, a lower voltage may allow for a more compact resonant transformer design and lower switching frequency. In some embodiments, off-the-shelf IGBTs can be driven in parallel rather than series and may require isolated drive circuitry.

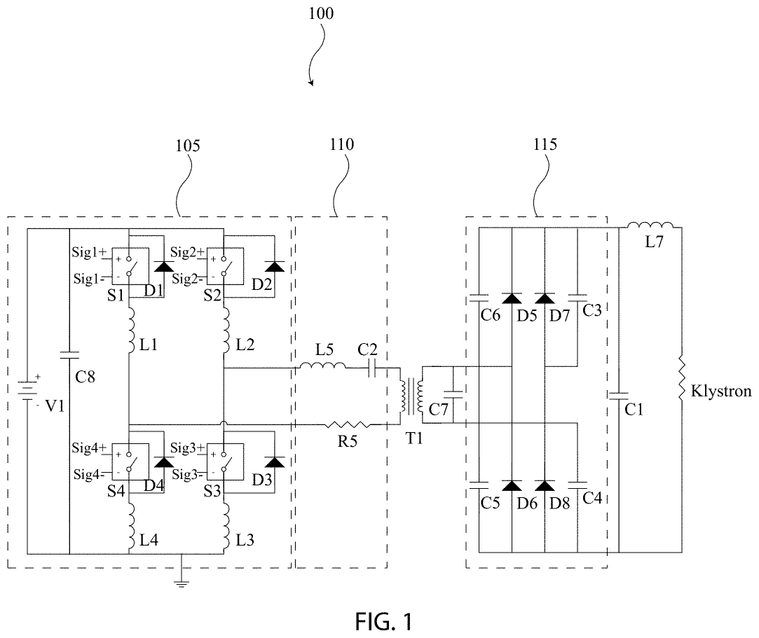

FIG. 1 is a circuit diagram of a resonant converter klystron driver 100 according to some embodiments. In some embodiments, the resonant converter klystron driver 100 can include three stages: a full-bridge circuit (or half-bridge circuit) 105, a resonant circuit 110 and step-up transformer T1, and/or a rectifier and filter stage 115. In some embodiments, the full-bridge circuit 105 may drive the resonant circuit 110 near its resonant frequency, which amplifies the input voltage according to the circuit's quality factor (Q) and can allow the solid-state switches to switch at near zero current, which may significantly reduce losses. The transformer T1 may step up the voltage to a higher voltage such as, for example, about 10 kV to about 200 kV such as, for example, 10 kV, 25 kV, 50 kV, 100kV, 150 V, 200 V, etc. The rectifier and filter stage 115 may convert the sinusoid to a 50 kV square pulse, which may drive the klystron.

In some embodiments, the resonant converter klystron driver 100 can produce an output voltage that has a ripple less than about ±1%. In some embodiments, the resonant converter klystron driver 100 may only deliver less than 10 J to the klystron during a fault. These may be competing requirements. For instance, larger filter elements may reduce ripple but store more energy. In addition, the values of the filter elements may be reduced to meet the ripple specification if the switching/resonant frequency of the converter is increased. However, increasing the switching frequency may increase the switching losses.

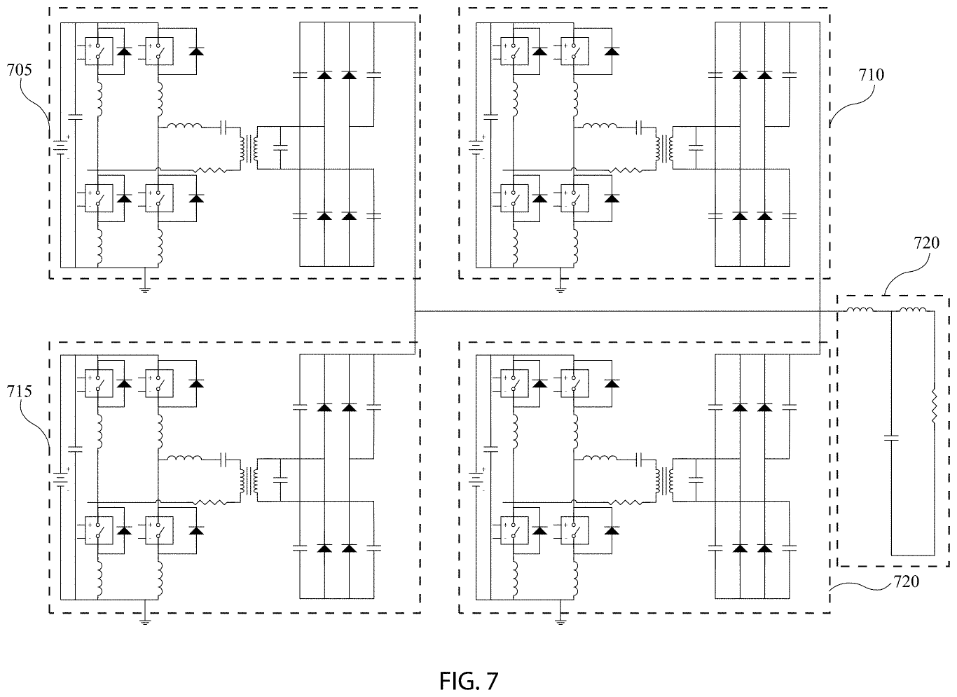

In some embodiments, four resonant converters may be used (e.g., as shown in FIG. 7) in parallel and operated 90° out of phase to drive a single klystron. In some embodiments, each resonant converter may have a switching frequency of 50 kHz, which may offer a balance between switching losses and transformer size. The four resonant converters may be connected in parallel between each respective rectifier stages and/or may include a common set of filter elements. When operated out of phase their combined frequency may be about 100 kHz-4 MHz, which may allow both the ripple and stored energy requirements to be satisfied. In some embodiments, each of the four resonant converters may deliver about 150 kW.

In some embodiments, with four resonant converters in parallel, an inductance of inductor L7 may be about 1 nH and a capacitance of capacitor C1 may be about 550 pF may be used to satisfy the ripple requirement. These values, for example, may be on order of the inductance and capacitance of the output cable of the klystron driver or may correspond to less than 1 J of stored energy.

In another embodiment, a high voltage switch (HVS) can be placed in parallel with the klystron to quickly dump energy contained in the filter elements during a fault. A fault, for example, may include a condition where the klystron begins to draw more or too much current form the power supply. This can occur, for example, due to an arc inside a klystron.

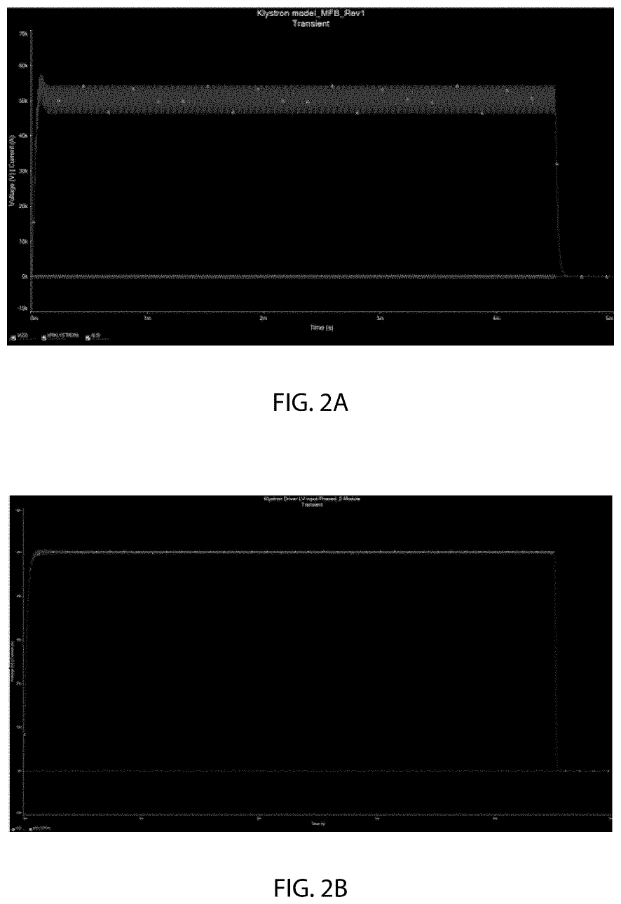

FIG. 2A shows output voltage from a single resonant converter klystron driver. FIG. 2B shows output voltage from a four resonant converter klystron driver where each resonant converter operate out of face relative to one another. Note the reduced jitter in the voltage output in FIG. 2B compared with FIG. 2A.

In some embodiments, the switches in the a full-bridge circuit 105 may include IGBTs with an appropriate body diode.

Driving a resonant circuit at resonance may provide, for example, two advantages: it can amplify the voltage of the input by the quality factor (Q) of the circuit or it can allow the H-bridge to switch at nearly zero current, which can significantly reduce switching losses. Since the Q may not be high enough to achieve the desired 50 kV output from the 600 V input, a high-voltage step-up transformer can be used to make up the difference. Allowing the resonant circuit to do some of the voltage amplification reduces the number of secondary turns in the transformer. In some embodiments, operating at a switching/resonant frequency as high as the switches can reasonably tolerate can reduce the size of the transformer's core. In this way, for example, the resonant topology can allow for a factor of 78 increase in voltage to be achieved with a relatively compact transformer.

In some embodiments, the size or complexity of the system can be reduced by using the inherent stray inductance of the transformer as the resonant inductor (e.g., inductor L5). The resonant capacitor can be designed to be a discrete element in series with the transformer (e.g., capacitor C2). In some embodiments, this capacitor can act as a blocking capacitor, which can prevent the transformer from saturating and damaging the system in the event of failure of the switching PCB or an incorrect triggering signal.

For example, with a resonant frequency of 50 kHz and a transformer's stray inductance of 19.5 the value of the resonant capacitor can be calculated to be 520 nF with the equation

$$f = \frac{1}{2 π \sqrt{LC}} .$$

This value can be achieved, for example, with a reasonable arrangement of commercially-available capacitors rated to the full primary-side voltage.

In some embodiments, a rectification and filter stage 115 may convert the sinusoidal output of the resonant circuit to a 50-kV square pulse with a ripple less than 1%. In some embodiments, one or more diodes (D5, D6, D7, and D8) may be included. In some embodiments, these diodes may be SiC Schottky diodes. In some embodiments, the diodes may include diodes with zero reverse recovery time (RRT). In some embodiments, diodes may include diodes with a small reverse recovery time.

In some embodiments, each leg of the rectifier can have six diodes in series to handle the 50-kV output. The number of parallel diode chains required was determined from calculations of energy dissipation in the diodes during a single shot according to the equation E=IVDt, where I is the forward current, Vis the forward voltage drop, D is the duty cycle, and t is the shot length. The forward current is sinusoidal, and the forward voltage drop is a function of this current, available on the diode datasheet. For this analysis a constant forward current at the peak value can be assumed, which introduces some safety factor into the design. The duty cycle for a full-wave rectifier may be 50% because current flows through a given side of the network for only half of the period. Adding multiple diode chains in parallel divides the current, resulting in less energy dissipated in each diode.

In some embodiments, the diodes can be used with heat sinks attached to each of their leads, which may also serve to electrically connect parallel diodes to each other. These heat sinks, for example, may significantly increase the thermal mass of the system and limit peak diode temperature. The following equation can be used to determine the mass of the heatsinks required to limit the diode temperature change to 10 ° C. over the ten-second shot length E=mcₚΔT, where m is the mass, cₚ is the specific heat, and ΔT is the change in temperature. The heat sinks may be designed to be made of copper due to its desirable electrical and thermal properties. Based on this energy analysis, a reasonably-sized rectifier can be made using three chains of these diodes in parallel. It is assumed that the time between shots will be long enough to allow the rectifier to be cooled by a small fan.

In some embodiments, the rectifier of a full-scale resonant converter may be capable of delivering 150 kW for 10 s and may use parallel chains and heat sinks. In some embodiments, the rectifier and filter stage 115 may include diodes or other components that may be spaced to not exceed 10 kV/inch to avoid, for example, corona formation and arcing. This can set the geometry and overall size of the full-wave rectifier; each vertex of the rectifier may be up to 50 kV from the opposing vertex.

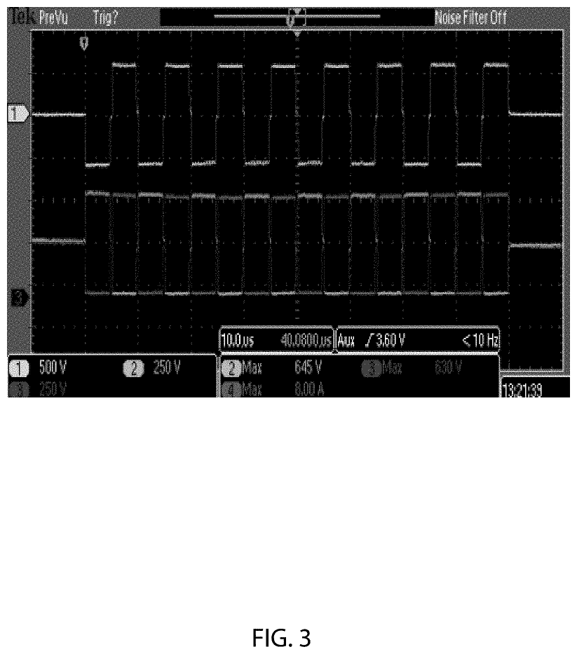

FIG. 3 are waveforms from a full-bridge resonant converter klystron driver coupled with a resistive load. Yellow represents the output voltage. Blue represents the VCE for switch 1 and Purple represents the VCE for switch 3. The output voltage (yellow) has an amplitude of 600 V and is nearly a square wave. The voltage waveforms across opposing switches (blue and purple) are nearly identical, 180° out of phase, and show no voltage spikes at the transitions.

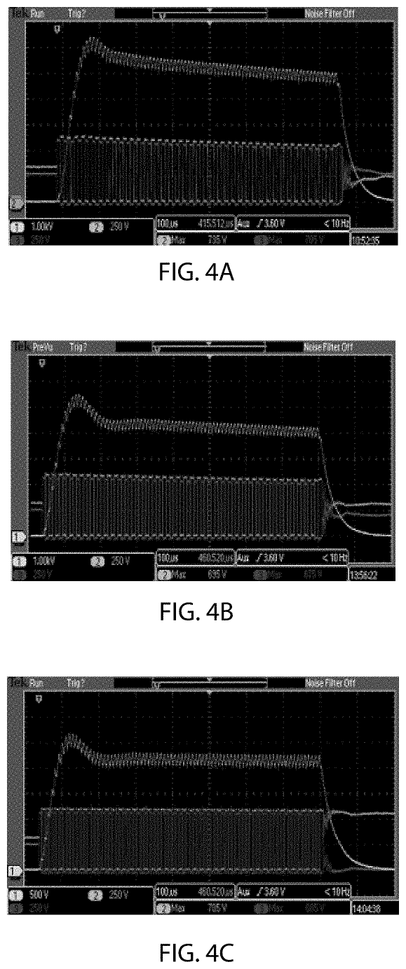

FIG. 4A, 4B, and 4C show results from a single resonant converter klystron driver with transformer and rectifier driving a resistive load according to some embodiments. These waveforms were created using a 16.7 kΩ resistive load, a charge voltage of 640 VAC, shot length of 800 μs, and varying duty cycles. The droop on the output voltage is the result of insufficient energy storage for 640 VAC; the 480 VAC should not have any droop issues. An output voltage of 50 kV can be achieved with a duty cycle of 84%. With a duty cycle of 74% the output voltage can be 40 kV, and at 50% duty cycle the output voltage can be 23 kV. This ability to adjust the output voltage by adjusting the duty cycle may allow a user to access different modes of the system at a fixed charge voltage. Furthermore, the user may employ a controller or pre-programmed triggering waveform to adjust the duty cycle during the 10 second shot, compensating for both energy storage droop and increased losses due to component heating.

The overshoot on the rising edge of the output waveform shown in FIG. 4A, 4B, and 4C may be due to the stray and filter inductance ringing into the filter capacitance. This can be mitigated using “soft start”, which involves slowly ramping up the duty cycle at the beginning of operation. This would increase the rise time of the output voltage somewhat, but in this example currently the rise time is only ˜8% of the maximum allowed so there is room available for this. A soft start can be achieved using a pre-programmed triggering waveform like that mentioned above.

These waveforms were produced with a single resonant converter show and have an output voltage had a ripple of about ±5%.

In order to reduce the ripple two or four resonant converter klystron driver that are in parallel and/or 180° out of phase. With two units in parallel a filter capacitance of 4 nF and zero additional inductance would reduce ripple below ±1%.

Some embodiments may include a two resonant converter klystron driver. The two resonant converters, for example, may be connected to each other in parallel. In some embodiments, a filter capacitor (e.g., a 1, 2, 4, 10, 20 nF capacitor) may be disposed between the two resonant converters.

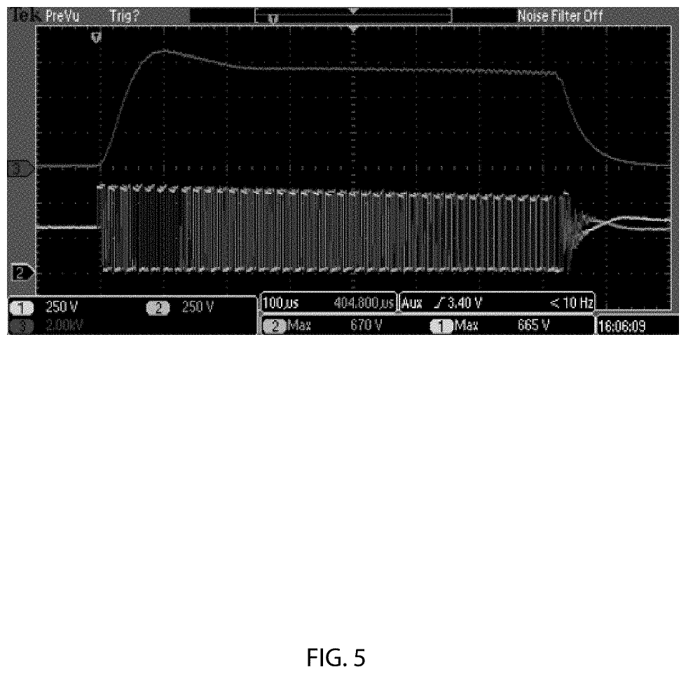

FIG. 5 are waveforms of the voltage output of a two resonant converter klystron driver according to some embodiments. These waveforms were created with a charge voltage of 640 V, a duty cycle of 84%, and an output voltage of 50 kV. In this example the resistive load was reduced to 8.33 kΩ to pull a current of 6 A total (e.g., 3 A from each converter). These waveforms show an output voltage ripple of 1.1%. Since the only filter element was a capacitance of 4 nF (capacitor C1 no L7) and the output voltage was 50 kV, the energy stored in this element was only 5 J. Thus, the two resonant converter klystron driver can produce a ±1% ripple and fault mitigation at 5 J.

The output voltage waveform has a fall time of ˜75 μs. This fall time is a function of the RC time of the load resistance and filter capacitance. For the full system the R may decrease by half to pull 12 A rather than 6 A, reducing the fall time by half. With four converters in parallel the filter capacitance can also be reduced to as low as 550 pF, which may also further reduce the stored energy and ripple.

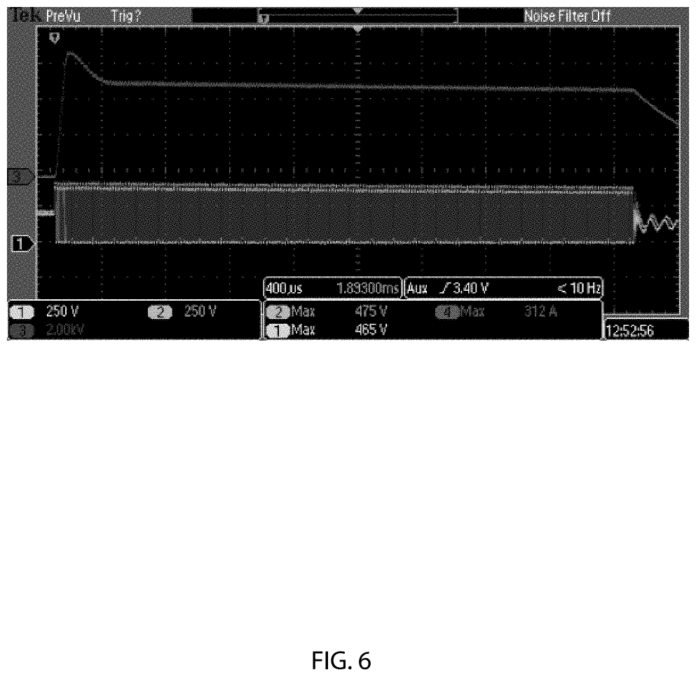

FIG. 6 are waveforms of the voltage output of a two resonant converter klystron driver according to some embodiments. These waveforms show the two resonant converter klystron driver can use longer shot durations by increasing the load resistance and thus decreasing the power. In this example, the waveforms are created with a 3.6 ms pulse, at 50 kV at 84% duty cycle from a 400 V charge voltage. In this example, the resistive load was 184 kΩ for a total current of 270 mA and power of 6.75 kW per resonant converter. This waveform shows a two resonant converter klystron driver can be scaled to longer shot durations.

Some embodiments include a resonant converter klystron driver that produces an output voltage of 50 kV with 1.1% ripple, an output current of 6 A per converter, or a power of 150 kW per converter for shot lengths up to 800 μs. Some embodiments also include longer shot lengths at lower output power may be capable of delivering 600 kW for 10 s.

FIG. 7 a circuit diagram of four full-bridge resonant converters 705, 710, 715, and 720 arranged in parallel driving a klystron load 725 according to some embodiments. Each of the full-bridge resonant converters 705, 710, 715, and 720 may be similar to or the same as the full-bridge resonant converter klystron driver 100 shown in FIG. 1.

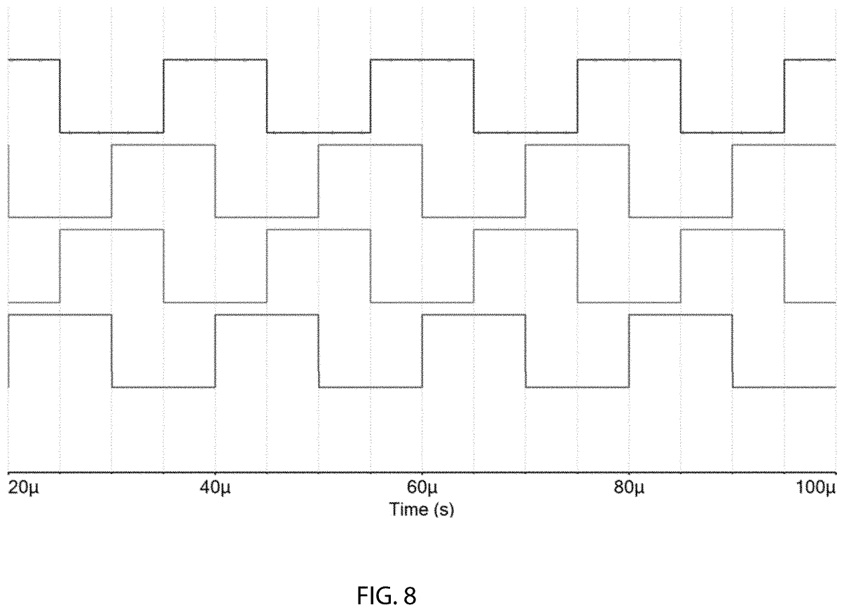

FIG. 8 is a waveform showing the output voltage of each of the full-bridge resonant converters in FIG. 7. The waveforms show the phasing of the output of each full bridge. These waveforms are measured at the input of the resonant circuit (e.g., V_{S1-S2}-VS_{S3-S4}). As shown, in this example, each full bridge is a quarter period out of phase. In some embodiments, 5, 6, 7, 8, . . . n full-bridge resonant converters may be arranged in parallel and each full-bridge resonant converter may operate 1/5^{th}, 1/6^{th}, 1/7^{th}, 1/8^{th}, . . 1/n^{th} out of phase, respectively.

Unless otherwise specified, the term “substantially” means within 5% or 10% of the value referred to or within manufacturing tolerances. Unless otherwise specified, the term “about” means within 5% or 10% of the value referred to or within manufacturing tolerances.

Numerous specific details are set forth herein to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

Some portions are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provides a result conditioned on one or more inputs. Suitable computing devices include multipurpose microprocessor-based computer systems accessing stored software that programs or configures the computing system from a general-purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied—for example, blocks can be re-ordered, combined, and/or broken into sub-blocks. Certain blocks or processes can be performed in parallel.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included herein are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

That which is claimed:

1. A resonant converter klystron driver comprising:
an input power supply;
a full-bridge circuit coupled with the input power supply;
a resonant circuit coupled with the full-bridge;
a step-up transformer coupled with the resonant circuit;
a rectifier coupled with a step-up transformer;
a filter stage coupled with the rectifier; and
an output coupled with the filter stage.

2. The resonant converter klystron driver according to claim 1, wherein the output is coupled with a klystron.

3. The resonant converter klystron driver according to claim 1, wherein the resonant circuit has a resonant frequency, and wherein the bridge circuit drives the resonant circuit at the resonant frequency.

4. The resonant converter klystron driver according to claim 1, wherein the filter stage comprises a capacitor and stray inductance.

5. The resonant converter klystron driver according to claim 1, wherein the output outputs a pulsed with an amplitude of about 50 kV with a ripple of about 1.1%.

6. The resonant converter klystron driver according to claim 1, wherein the input power supply produces 13.8 kVAC, 480 VAC, or 600 V.

7. The resonant converter klystron driver according to claim 1, wherein the output outputs an output current of about 12 A.

8. A resonant converter klystron driver comprising:
an input power supply;
a half-bridge coupled with the input power supply;
a resonant circuit coupled with the full-bridge;
a step-up transformer coupled with the resonant circuit;
a rectifier coupled with a step-up transformer;
a filter stage coupled with the rectifier; and
an output coupled with the filter stage.

9. The resonant converter klystron driver according to claim 8, wherein the output is coupled with a klystron.

10. The resonant converter klystron driver according to claim 8, wherein the input power supply produces 13.8 kVAC, 480 VAC, or 600 V.

11. The resonant converter klystron driver according to claim 8, wherein the output outputs a pulsed with an amplitude of about 50 kV with a ripple of about 1.1%.

12. The resonant converter klystron driver according to claim 8, wherein the resonant circuit has a resonant frequency, and wherein the bridge circuit drives the resonant circuit at the resonant frequency.

13. A resonant converter klystron driver comprising:
an input power supply;
a plurality of driver circuits arranged in parallel, each circuit comprising:
a bridge circuit coupled with the input power supply;
a resonant circuit coupled with the bridge circuit;
a step-up transformer coupled with the resonant circuit;
a rectifier coupled with a step-up transformer; and
a filter stage coupled with the rectifier; and
an output coupled with the filter stage.

14. The resonant converter klystron driver according to claim 13, wherein the output is coupled with a klystron.

15. The resonant converter klystron driver according to claim 13, where n represents the number of driver circuits, and wherein the bridge circuits of the plurality of driver circuits are 1/n^{th} out of phase with respect to each the other bridge circuits.

16. The resonant converter klystron driver according to claim 13, wherein the resonant circuit has a resonant frequency, and wherein the bridge circuit drives the resonant circuit at the resonant frequency.

17. The resonant converter klystron driver according to claim 13, wherein the bridge circuit comprises either a half-bridge circuit or a full-bridge circuit.

18. The resonant converter klystron driver according to claim 13, wherein the filter stage comprises a capacitor and stray inductance.

19. The resonant converter klystron driver according to claim 13, wherein the output outputs a pulsed with an amplitude of about 50 kV with a ripple of about 1.1%.
